(19) United States
(12) Patent Application Publication
(10) Pub. No.: US 2025/0218813 A1
(43) Pub. Date: Jul. 3, 2025

(54) CHEMICAL SUPPLY APPARATUS AND CHEMICAL SUPPLY METHOD

(71) Applicant: Semes Co., Ltd, Cheonan-si (KR)

(72) Inventors: Jin Ah HAN, Cheonan-si (KR); Yong Hoon HONG, Seoul (KR)

(73) Assignee: Semes Co., Ltd, Cheonan-si (KR)

(21) Appl. No.: 19/004,619

(22) Filed: Dec. 30, 2024

(30) Foreign Application Priority Data
Dec. 29, 2023 (KR) 10-2023-0197550

(51) Int. Cl. H01L 21/67; B08B 9/032; B08B 9/08

(52) U.S. Cl. CPC H01L 21/67051; B08B 9/032; B08B 9/08; B08B 2209/032; B08B 2209/08

(57) ABSTRACT

The present invention provides a chemical supply apparatus of a liquid processing apparatus. The chemical supply apparatus of a liquid processing apparatus includes: a first tank supplying a chemical to the substrate processing apparatus and recovering a chemical used in the substrate processing apparatus; a second tank mixing chemicals and supplying the mixed chemical to the first tank; a liquid supplier supplying a chemical to the first tank and the second tank; and a controller performing a liquid exchange mode for supplying a new chemical to the first tank when a lifetime of a chemical stored in the first tank reaches a lifetime, and controlling the tanks and the chemical supplier such that liquid is supplied to the substrate processing apparatus from the second tank in the liquid exchange mode.

### CROSS-REFERENCE TO RELATED APPLICATIONS

This application claims priority to and the benefit of Korean Patent Application No. 10-2023-0197550 filed in the Korean Intellectual Property Office on Dec. 29, 2023, the entire contents of which are incorporated herein by reference.

### TECHNICAL FIELD

The present invention relates to a chemical supply apparatus and a chemical supply method.

### BACKGROUND ART

Contaminants such as particles, organic contaminants, and metallic contaminants remaining on a substrate surface significantly affect the characteristics and production yields of semiconductor devices. For this reason, a cleaning process of removing various contaminants attached to a substrate surface is very important in a semiconductor manufacturing process, and a process of cleaning a substrate is performed before and after each unit process for manufacturing a substrate. As a process for removing such contaminants, there is a cleaning process using deionized water or a chemical.

The chemicals used in the substrate cleaning process can be recovered for reuse. However, as the number of reuse cycles of chemicals increases, issues arise, such as the concentration of chemicals deviating from the standard concentration and the presence of fine particles remaining in chemicals. Accordingly, when a chemical reaches its lifetime or there is a change in its concentration, a liquid exchange of completely discharging a remaining chemical and replacing it with a new chemical is performed.

However, as a new chemical in a tank mixes with a residual chemical remaining in the tank or a pipe (circulation line), the concentration of the new chemical deviates, thereby leading to changes in the process performance.

For example, when a chemical is continuously used in the process of etching a TiN film on a substrate, Ti ions dissolve into the chemical. When a chemical with a high concentration of Ti ions is simply replaced through a liquid exchange, it not only introduces defects due to the lifetime but also causes a decrease in stability of the chemical as the high-concentration Ti-ion chemical mixes with a new chemical and gets diluted (Ti ions are a factor that affects the etching rate of TiN by decomposing H₂O₂).

### SUMMARY OF THE INVENTION

An objective of the present invention is to provide a chemical supply apparatus and a chemical supply method that can supply a chemical to a substrate processing unit in a liquid exchange process of replacing a chemical reaching its lifetime with a new chemical.

An objective of the present invention is to provide a chemical supply apparatus and a chemical supply method that can maintain the concentration of Ti in a recovered chemical can be maintained at a specific value or less during the lifetime of the chemical.

An objective of the present invention is to provide a chemical supply apparatus and a chemical supply method that can prevent deviation of the concentration of a chemical in a liquid exchange process in a tank.

The objectives of the present invention are not limited thereto and other objectives not stated herein may be clearly understood by those skilled in the art from the following description.

According to an aspect of the present disclosure, there may be provided a chemical supply apparatus including: a first tank supplying a chemical to the substrate processing apparatus and recovering a chemical used in the substrate processing apparatus; a second tank mixing chemicals and supplying the mixed chemical to the first tank; a chemical supplier supplying a chemical to the first tank and the second tank; and a controller performing a chemical exchange mode for supplying a new chemical to the first tank when a chemical stored in the first tank reaches its lifetime, and controlling the tanks and the chemical supplier such that a chemical is supplied to the substrate processing apparatus from the second tank in the chemical exchange mode.

Further, the controller may be configured to control such that a chemical used during an early stage of processing one sheet of substrate in the substrate processing apparatus is discarded through a drain line and only the chemical used thereafter is recovered to the first tank through a recovery line.

Further, the controller may be configured to control such that the first tank is supplemented with a chemical from the second tank as needed, such that a specific component of the chemical stored in the first tank is maintained below a predetermined concentration.

Further, the amount of the chemical added to the first tank from the second tank may correspond a difference between a supply amount supplied to the substrate processing apparatus from the first tank and a recovery amount recovered to the first tank from the substrate processing apparatus.

Further, the second tank may receive a chemical from the chemical supplier, and the chemical is mixed and heated in the second tank.

Further, the second tank may include: a circulation line; a chemical supplement line branching from the circulation line and supplying a chemical to the first tank; and a sub-supply line branching from the chemical supplement line and connected with a supply line of the substrate processing apparatus.

Further, the controller may be configured to control such that, in the chemical exchange mode, the chemical accommodated in the first tank is drained, a flushing liquid is fed into the first tank, circulated, and then drained, and the new chemical is supplied to the first tank to achieve chemical exchange.

Further, the controller may be configured to control such that, in the chemical exchange mode, a flushing process of feeding the flushing liquid into the first tank, circulating, and then draining the flushing liquid is performed multiple times.

Further, the flushing liquid may be the same as the new chemical, and the flushing liquid may be supplied to the first tank through the chemical supplier.

According to another aspect of the present disclosure, there may be provided a chemical supply method that supplies a chemical to a substrate processing apparatus from a chemical processing apparatus having a first tank and a second tank, the chemical supply method including: supplying a chemical stored in the first tank to the substrate processing apparatus and recovering a chemical used in the substrate processing apparatus to the first tank; supplementing the first tank with a chemical in the second tank as needed; and a chemical exchange step of supplying a new chemical to the first tank when the liquid stored in the first tank reaches its lifetime, wherein the chemical in the second tank is supplied to the substrate processing apparatus in the liquid exchange step.

Further, the chemical used in the substrate processing apparatus may not be recovered but may be drained in the chemical exchange step.

Further, a chemical used in an early stage of processing one sheet of substrate in the substrate processing apparatus may be discarded and only the chemical used thereafter may be recovered to the first tank.

Further, the supplementing of the first tank with the chemical in the second tank as needed, may supplement the first tank with the chemical from the second tank as needed, such that a specific component in the chemical stored in the first tank is maintained below a specific concentration.

Further, the amount of the supplemented chemical may correspond a difference between a supply amount supplied to the substrate processing apparatus from the first tank and a recovery amount recovered to the first tank from the substrate processing apparatus.

Further, the chemical exchange step may drain the chemical accommodated in the first tank, may feed a flushing liquid into the first tank, circulate and then drain the flushing liquid, and may supply the new chemical to the first tank, thereby achieving chemical exchange.

Further, the chemical exchange step may perform a flushing process using the flushing liquid at least twice.

Further, the flushing liquid may be the same as the new chemical.

According to another aspect of the present invention, there may be provided a chemical supply method that supplies a chemical to a substrate processing apparatus from a chemical processing apparatus having a first tank and a second tank, the chemical supply method including: supplying a chemical stored in the first tank to the substrate processing apparatus, discarding a chemical used in an early stage of the substrate processing apparatus, and recovering only the chemical used thereafter to the first tank; supplementing the first tank with a chemical from the second tank as needed, such that a specific component of the chemical stored in the first tank is maintained below a predetermined concentration; and a chemical exchange step of supplying a new chemical to the first tank when the chemical stored in the first tank reaches its lifetime, wherein, in the chemical exchange step, the chemical in the second tank is supplied to the substrate processing apparatus and the chemical used in the substrate processing apparatus is not recovered but is drained.

Further, the amount of the supplemented chemical may correspond a difference between a supply amount supplied to the substrate processing apparatus from the first tank and a recovery amount recovered to the first tank from the substrate processing apparatus, and the chemical exchange step may drain the chemical accommodated in the first tank, may feed a flushing liquid into the first tank, circulate and then drain the flushing liquid, and may supply the new chemical to the first tank, thereby achieving chemical exchange.

Further, the chemical exchange step may perform a flushing process using the flushing liquid at least twice, and the flushing liquid may be the same as the new chemical.

According to an embodiment of the present invention, it is possible to supply a chemical to a substrate processing unit in a liquid exchange step of replacing a chemical reaching a lifetime with a new chemical.

According to an embodiment of the present invention, it is possible to maintain the concentration of Ti in a recovered chemical at a specific value or less during the lifetime of the chemical.

According to an embodiment of the present invention, it is possible to prevent deviation of the concentration of a chemical in a liquid exchange process in a tank.

According to an embodiment of the present invention, it is possible to can secure stability in processes by preventing deviation of the concentration of a chemical in the process of replacing a chemical passing a lifetime with a new chemical.

Effects of the present invention are not limited to those described above and effects not stated above will be clearly understood to those skilled in the art from the specification and the accompanying drawings.

### BRIEF DESCRIPTION OF THE DRAWINGS

FIG. 1 shows a substrate processing apparatus according to an embodiment of the present invention.

FIG. 2 is a view schematically showing an embodiment of the liquid processing chamber of FIG. 3.

FIG. 3 is a view illustrating a chemical supply apparatus connected to the liquid processing chamber.

FIG. 4 is a flowchart illustrating a chemical supply method in the liquid supply apparatus.

FIG. 5 to FIG. 7 are views sequentially showing the chemical supply method.

### DETAILED DESCRIPTION

Embodiments of the present invention will be described in detail with reference to the accompanying drawings for those skilled in the art to be able to easily implement he present invention. However, the present invention may be modified in various different ways and is not limited to the embodiments described herein. Further, in the following description of preferred embodiments of the present invention, when it is determined that detailed description of related well-known functions or configurations may make the spirit of the present invention unclear, they are not described in detail. Further, parts having similar functions and operations are given the same reference numerals throughout the drawings.

Unless described otherwise, “including” any components will be understood to imply the including of other components but not the exclusion of any other components. In detail, it will be further understood that the terms “comprises” or “have” used in this specification, specify the presence of stated features, steps, operations, components, parts, or a combination thereof, but do not preclude the presence or addition of one or more other features, numerals, steps, operations, components, parts, or a combination thereof.

Singular forms are intended to include plural forms unless the context clearly indicates otherwise. Further, the shapes and sizes of the components in the drawings may be exaggerated for more clear explanation.

It will be understood that, although the terms first, second, etc. may be used herein to describe various components, these components should not be limited by these terms. The terms are used only to distinguish one component from another component. For example, the ‘first’ component may be named the ‘second’ component, and vice versa, without departing from the scope of the present invention.

It is to be understood that when one element is referred to as being “connected to” or “coupled to” another element, it may be connected directly to or coupled directly to another element or be connected to or coupled to another element, having the other element intervening therebetween. On the other hand, it should to be understood that when one element is referred to as being “connected directly to” or “coupled directly to” another element, it may be connected to or coupled to another element without the other element intervening therebetween. Meanwhile, the terms used herein to describe a relationship between elements, that is, “between”, “directly between”, “adjacent” or “directly adjacent” should be interpreted in the same manner as those described above.

Unless otherwise defined, all terms including technical and scientific terms used herein have the same meanings as commonly understood by those skilled in the art to which the present invention belongs. It must be understood that the terms defined by the dictionary are identical with the meanings within the context of the related art, and they should not be ideally or excessively formally defined unless the context clearly dictates otherwise.

The term ‘chemical’ refers to a processing liquid used in the substrate processing apparatus, including but not limited to cleaning solutions, etching solutions, or developing solutions.

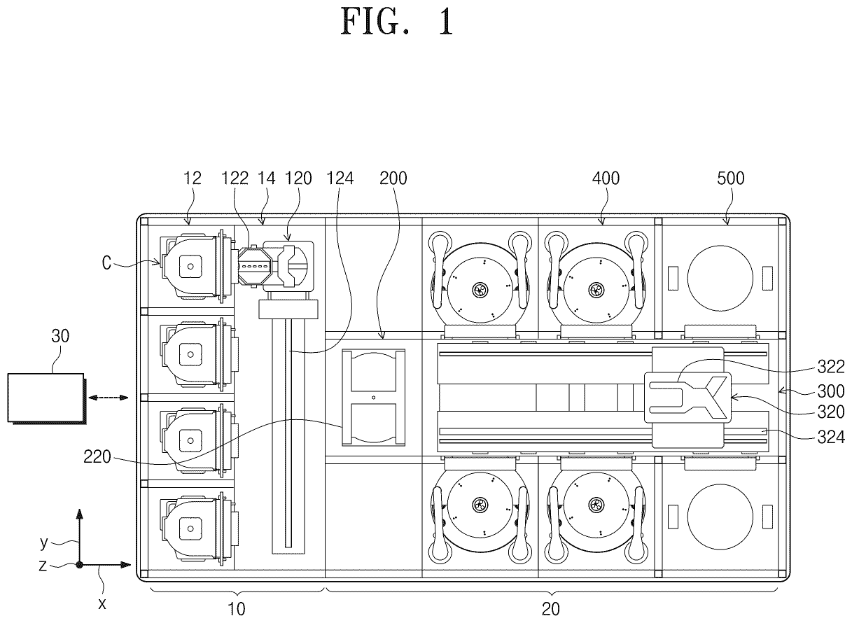

Hereafter, embodiments of the present invention are described with reference to FIG. 1 to FIG. 7.

FIG. 1 shows a substrate processing apparatus according to an embodiment of the present invention.

Referring to FIG. 1, a substrate processing apparatus includes an index module 10, a processing module 20, and a control unit 30. When seen from above, the index module 10 and the processing module 20 are disposed in one direction. Hereafter, the direction in which the index module 10 and the processing module 20 are arranged is referred to as a first direction X, a direction perpendicular to the first direction X when seen from above is referred to as a second direction Y, and a direction perpendicular to both of the first direction X and the second direction Y is referred to as a third direction Z.

The index module 10 transfers substrates W to the processing module 20 from containers C accommodating the substrates W and puts the substrates W processed at the processing module 20 into the containers C. The longitudinal direction of the index module 10 is provided in the second direction Y. The index module 10 has a load port 12 and an index frame 14. The load port 12 is positioned at the opposite side to the processing module 20 with the index frame 14 therebetween. The containers C accommodating substrates W are placed in the load port 12. A plurality of load ports 12 may be provided and the plurality of load ports 12 may be disposed in the second direction Y.

The container C may be a container for sealing such as a Front Open Unified Pod (FOUP). The container C may be placed in the load port 12 by a worker or a conveying device (not shown) such as an overhead transfer, an overhead conveyor, or an automatic guided vehicle.

An index robot 120 is provided at the index frame 14. A guide rail 124 of which the longitudinal direction is provided in the second direction Y is provided in the index frame 14 and the index robot 120 may be provided to be movable on the guide rail 124. The index robot 120 includes a hand 122 on which substrates W are placed and the hand 122 may be provided to be able to move forward and backward, rotate about the third direction Z, and move in the third direction Z. A plurality of hands 122 may be provided to be spaced apart from each other in the up-down direction and the hands 122 can move forward and backward independently from each other.

The control unit 30 can control the substrate processing apparatus. The control unit 30 may include: a process controller that is a microprocessor (computer) that performs control of the substrate treatment device; a user interface that is a keyboard through which an operator performs command input operation, etc. to manage the substrate treatment device, a display that visualizes and displays the operation situation of the substrate treatment device, etc.; and a memory that stores a control program for performing treatment, which is performed in the substrate treatment device, under control of the process controller, a program for performing treatment on each component in accordance with various data and treatment conditions, that is, a treatment recipe. Further, the user interface and the memory may be connected to the process controller. The processing recipe may be stored in a memory medium of the memory and the memory medium may be a hard disk and may be a portable disc such as a CD-ROM and a DVD, and a semiconductor memory such as a flash memory.

The processing module 20 includes a buffer unit 200, a transfer chamber 300, a liquid processing chamber 400, and a drying chamber 500. The buffer unit 200 provides a space in which substrates W that are loaded into the processing module 20 and substrates W that are unloaded from the processing module 20 temporarily stay. The liquid processing chamber 400 performs a liquid processing process of performing liquid processing on substrates W by supplying liquid onto the substrates W. The drying chamber 500 can perform a drying process that removes liquid remaining on substrates W. The transfer chamber 300 transfers substrates W between the buffer unit 200, the liquid processing chamber 400, and the drying chamber 500.

The longitudinal direction of the transfer chamber 300 may be provided in the first direction X. The buffer unit 200 may be disposed between the index module 10 and the transfer chamber 300. The liquid processing chamber 300 and the drying chamber 500 may be disposed on sides of the transfer frame 300. The liquid processing chamber 400 and the transfer chamber 300 may be disposed in the second direction Y. The drying chamber 500 and the transfer chamber 300 may be disposed in the second direction Y. The buffer unit 200 may be positioned at an end of the transfer chamber 300.

According to an embodiment, the liquid processing chambers 400 are disposed at both sides of the transfer chamber 300, the drying chambers 500 are disposed at both sides of the transfer chamber 300, and the liquid processing chambers 400 may be disposed at positions close to the buffer unit 200 in comparison to the drying chambers 500. The liquid processing chambers 400 may be provided in an array of A×B (A and B are each a natural number of 1 or more) in the first direction X and the third direction Z, respectively, at a side of the transfer chamber 300. The drying chambers 500 may be provided by the number of C×D (C and D are each a natural number of 1 or more) in the first direction X and the third direction Z, respectively, at a side of the transfer chamber 300. Unlike the above description, only the liquid processing chambers 400 may be provided at a side of the transfer chamber 300 and only the drying chambers 500 may be provided at another side.

The transfer chamber 300 has a transfer robot 320. A guide rail 324 of which the longitudinal direction is provided in the first direction X is provided in the transfer chamber 300 and the transfer robot 320 may be provided to be movable on the guide rail 324. The transfer robot 320 includes a hand 322 on which substrates W are placed and the hand 322 may be provided to be able to move forward and backward, rotate about the third direction Z, and move in the third direction Z. A plurality of hands 322 may be provided to be spaced apart from each other in the up-down direction and the hands 322 can move forward and backward independently from each other.

The buffer unit 200 has a plurality of buffers 220 on which substrates W are placed. The buffers 220 may be disposed to be spaced apart from each other in the third direction Z. The buffer unit 200 is open on the front face and the rear face. The front face is a surface that faces the index module 10 and the rear face is a surface that faces the transfer chamber 300. The index robot 120 can approach the buffer unit 200 through a front face and the transfer robot 320 can approach the buffer unit 200 through a rear face.

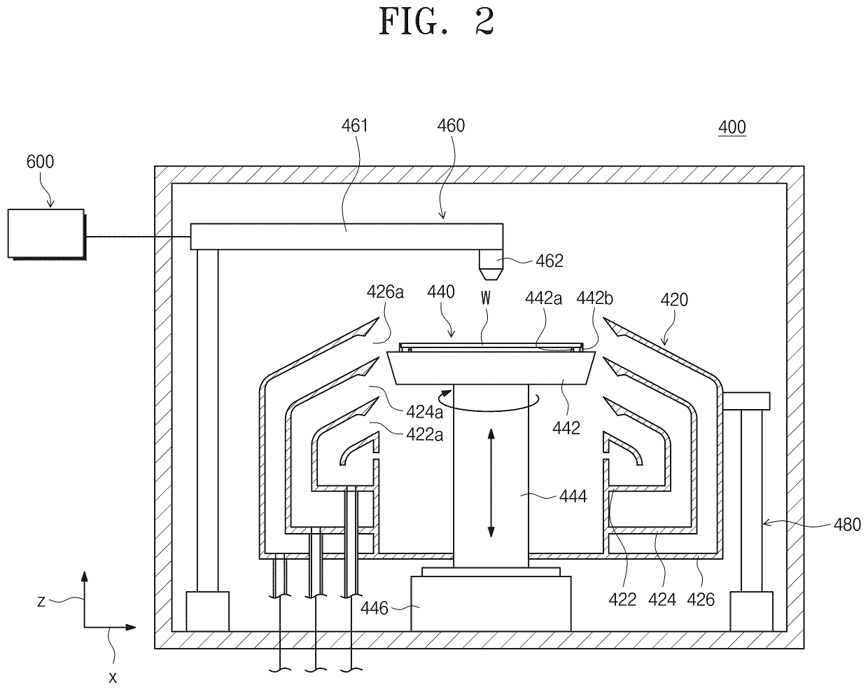

FIG. 2 is a view schematically showing an embodiment of the liquid processing chamber of FIG. 1.

Referring to FIG. 2, the liquid processing chamber 400 includes a housing 410, a cup 420, a supporting unit 440, and a liquid spray unit 460, and an elevation unit 480.

The housing 410 may have an internal space in which substrates W are processed. The housing 410 may have a hexahedral shape. For example, the housing 410 may have a rectangular prism shape. Further, an opening (not shown) through which substrates W are loaded or unloaded may be formed on the housing 410. Further, a door (not shown) selectively opening and closing the opening may be installed on the housing 410.

The cup 420 may have a box shape with open top. The cup 420 may have a processing space and substrates W can be liquid-processed in the processing space. The supporting unit 440 supports substrates W in the processing space. The liquid spray unit 460 discharges a processing liquid to a substrate W supported on the supporting unit 440. A plurality of kinds of processing liquids is provided and may be sequentially supplied to a substrate W. The elevation unit 480 adjusts the relative height between the cup 420 and the supporting unit 440.

According to an example, the cup 420 has a plurality of recovery baths 422, 424, and 426. The recovery baths 422, 424, and 426 each have a recovery space for recovering liquid used to process a substrate. The recovery baths 422, 424, and 426 are each provided in a ring shape surrounding the supporting unit 440. The processing liquids splashed by rotation of a substrate when the liquid processing process is performed flow into the recovery spaces through inlets 422a, 424a, and 426a of the recovery baths 422, 424, and 426, respectively. According to an example, the cup 420 has a first recovery bath 422, a second recovery bath 424, and a third recovery bath 426. The first recovery bath 422 is disposed to surround the supporting unit 440, the second recovery bath 424 is disposed to surround the first recovery bath 422, and the third recovery bath 426 is disposed to surround the second recovery bath 424. The second inlet 424a for supplying liquid into the second recovery bath 424 may be positioned higher than the first inlet 422a for supplying liquid into the first recovery bath 422, and the third inlet 426a for supplying liquid into the third recovery bath 426 may be positioned higher than the second inlet 424a.

The supporting unit 440 has a supporting plate 442 and an actuating shaft 444. The upper surface of the supporting plate 442 is provided substantially in a circular shape and may have a diameter larger than substrates W. Supporting pins 442a supporting the rear surface of a substrate W is provided at the center portion of the supporting plate 442 and the upper ends of the supporting pins 442a protrude from the supporting plate 442 to space a substrate W a predetermined distance from the supporting plate 442. Chuck pins 442b are provided on the edge portion of the supporting plate 442. The chuck pins 442b protrude upward from the supporting plate 442 and support the side of a substrate W to prevent the substrate W from separating from the supporting unit 440 when the substrate W is rotated. The actuating shaft 444 is driven by an actuator 446, is connected with the center of the underside of a substrate W, and rotates the supporting plate 442 about the center axis thereof.

According to an embodiment, the liquid spray unit 460 may include a nozzle 462. The nozzle 462 can discharge processing liquid to a substrate W. The processing liquid may be a chemical, a rinse solution, or an organic solvent. The chemical may be a chemical that has the property of strong acid or strong base. Further, the liquid spray unit 460 may include a plurality of nozzles 462 and the nozzles 462 can discharge different kinds of processing liquid. For example, any one of the nozzles 462 may discharge a chemical, another one of the nozzles 462 may discharge a rinse solution, and another one of the nozzles 462 may discharge an organic solvent. The liquid spray unit 460 is supplied with processing liquid (chemical) from a chemical supply apparatus 600.

The present invention can be applied to a wet etching process or a cleaning process of removing the film on a substrate surface and various processing liquids can be used in the process. The processing liquid that can be used in the present invention may include at least any one or more substances selected from hydrofluoric acid (HF), sulfuric acid (H₃SO4), hydrogen peroxide (H₂O₂), nitric acid (HNO₃), phosphoric acid (H₃PO₄), ozonized water, SC-1 solution (a mixture of ammonium hydroxide (NH₄OH), hydrogen peroxide (H₂O₂), and water (H₂O)), and may include processing liquid of various other substances that can be used in a substrate processing process.

The elevation unit 480 moves the cup 420 in the up-down direction. The relative height between the cup 420 and a substrate W is changed by up-down movement of the cup 420. Accordingly, the recovery tubs 422, 424, and 426 that recover liquids are changed, depending on the kinds of processing liquids that are supplied to substrates W, so it is possible to separately recover processing liquids. Unlike the above description, the cup 420 may be fixed and the elevation unit 480 may move the supporting unit 440 in the up-down direction.

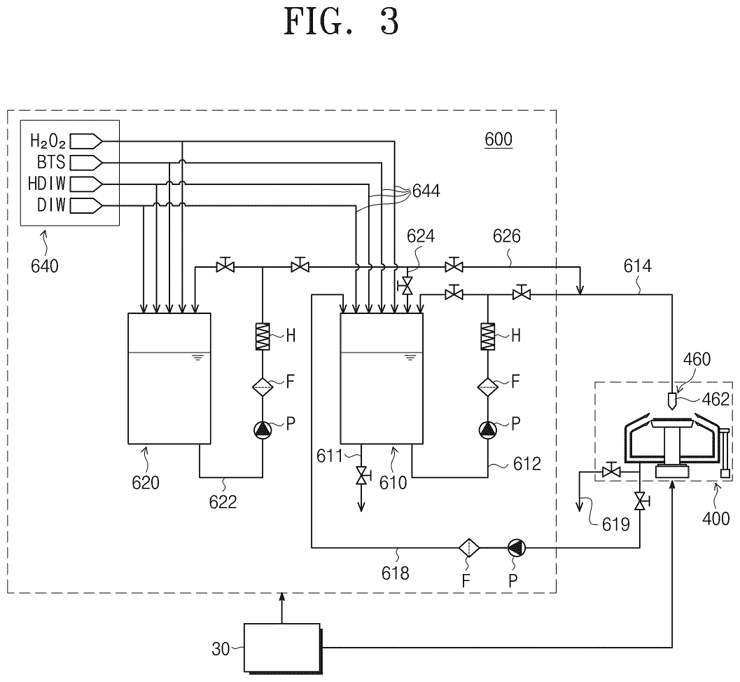

FIG. 3 is a view illustrating a chemical supply apparatus connected to the liquid processing chamber.

Referring to FIG. 3, the chemical supply apparatus 600 supplies a chemical that is used to process substrates to the liquid processing chamber 400.

The chemical supply apparatus 600 may be provided to supply a chemical to a plurality of liquid processing chambers 400. A process of etching a TiN film on a substrate. When a chemical is continuously reused in the process of etching a TiN film, the concentration of TiN ions in the chemical increases. When a chemical with high concentration of Ti ions and a new chemical are mixed, the stability of the chemical may be deteriorated. Accordingly, a flushing process of removing the chemical remaining in the tanks and the circulation line of the chemical supply apparatus before supplying a new chemical is very important. Further, an operation of preventing supply of a chemical to the liquid processing chamber 400 from stopping when changing the liquid in the tanks is important.

For example, the chemical supply apparatus 600 may include a first tank 610, a second tank 620, a chemical supplier 640, and a controller 30. The controller 30 can control the first tank 610, the second tank 620, and the chemical supplier 640.

The first tank 610 is tank that receives a chemical used in the liquid processing chamber 400 and recycles the chemical and a main tank as well that supplies a chemical to the liquid processing chamber 400. The second tank 620 is a mixing tank that receives raw liquid from the chemical supplier 640 and mixes it and adjusts the temperature and a supplement tank as well that continuously add a chemical by the loss of chemical from the first tank 610.

The first tank 610 may include a first circulation line 612, a main supply line 614, and a recovery line 618. The main supply line 614 may by connected to the nozzle 462 of the liquid spray unit 460 shown in FIG. 2. The first circulation line 612 circulates the chemical stored in the first tank 610. A pump P, a filter F, and a heater H may be installed in the first circulation line 612.

The liquid processing chamber 400 is connected with the first tank 610 through recovery line 618. The chemical used in the liquid processing chamber 400 can be recovered to the first tank 610 through the recovery line 618. A filter F and a pump P can be installed in the recovery line 618. A drain line 619 is connected to the recovery line 618. The drain line 619 may be provided adjacent to the liquid processing chamber 400. A portion of the chemical used in the liquid processing chamber 400 can be discarded through the drain line 619. The chemical that is discarded may be limited to the initial amount of the chemical that is discharged from the liquid processing chamber 400. Since a high level of impurities are contained in the initial amount of chemical, when all the chemical is recovered to the first tank 610, it leads to an increase in the concentration of the chemical impurities in the first tank 610 (e.g., a increase in concentration of Ti ions). Accordingly, it is possible to reduce an increase of the concentration of impurities in the first tank 610 by discarding the initial amount of chemical that is discharged from the liquid processing chamber 400. For example, assuming that a chemical is supplied to the liquid processing chamber 400 from the first tank 610 for 10 seconds, it is preferable to discard the chemical through the drain line 619 in the early stage of discharging the chemical from the liquid processing chamber 400 and then recover the chemical to the first tank 610 through the recovery line 618 thereafter.

The first tank 610 can be supplemented with a fresh chemical so that the chemical recovered through the recovery line 618 can be reused, whereby the concentration of Ti ions in the chemical can be adjusted (maintained). The fresh chemical for adjusting the concentration of a chemical may be supplied through the second tank 620, as needed. Accordingly, it is possible to maintain the concentration of Ti ions in the chemical in the first tank 610 at a predetermined level during a lifetime. A new chemical that is added to the first tank 610 is provided from the second tank 620. A first drain line 611 is provided on the lower end of the first tank 610. The chemical reaching a lifetime can be drained through the first drain line 611 in liquid exchange for the first tank.

Meanwhile, source supply lines 644 for receiving raw liquids from the chemical supplier 640 in liquid exchange may be connected to the first tank 610. For example, the chemical supplier 640 can supply high-temperature deionized water, deionized water, Beol Tin Strip (BTS), hydrogen peroxide (H₂O₂), etc. to the first tank 610.

The second tank 620 may include a second circulation line 622, liquid supplement line 624, and a sub-supply line 626. The second circulation line 622 circulates the chemical stored in the second tank 620. A pump P, a filter F, and a heater H may be installed in the second circulation line 622. The pump P, filter F, and heater H installed in the second circulation line can be used to mix the chemical in the second tank 620. The liquid supplement line 624 may diverge from the second circulation line 622 and may be connected to the first tank 610. The sub-supply line 626 may diverge from the liquid supplement line 624 and may be connected to the main supply line 614.

The second tank 620 supplements the first tank 610 with a fresh chemical for maintaining the concentration of a chemical, as needed. Further, the second tank 620 supplies a chemical to the liquid spray unit 460 in a liquid exchange mode for the first tank 610. The chemical is supplied to the nozzle 462 of the liquid spray unit 460 through the sub-supply line 626.

Meanwhile, source supply lines 644 for receiving raw liquids from the chemical supplier 640 may be connected to the second tank 620. For example, the chemical supplier 640 can supply high-temperature deionized water, deionized water, Beol Tin Strip (BTS), hydrogen peroxide (H₂O₂), etc. to the second tank 620. The chemical supplier 640 can supply raw liquids to the second tank 620 when the chemical level in the second tank 620 drops below a predetermined level.

Valves installed for the first tank 610 and the second tank 620 can be controlled by the controller 30.

The processing liquid supplier 640 can supply a flushing chemical for flushing the first tank 610 and the circulation line connected to the first tank 610 in a flushing mode. The flushing chemical may be the same as the chemical that is used in processes. The chemical supplier 640 can supply chemicals to the first tank 610 when the flushing mode is finished.

The controller 30 can control the tank 610 and the chemical supplier 640 to perform a flushing mode in which the chemical (existing chemical) accommodated in the first tank 610 is drained and a flushing chemical is fed into the first tank 610, circulated, and then drained and a liquid exchange mode in which liquid exchange is performed by supplying a new chemical to the first tank. It is preferable that the flushing mode that feeds a flushing chemical into the first tank, and then circulates and drains the fresh chemical is performed repeatedly at least one times.

Further, the controller 30 can perform control such that the chemical in the second tank 620 is supplied to the liquid spray unit 460 to prevent supply of a chemical to the liquid spray unit 460 from being stopped in liquid exchange for the first tank 610. While liquid exchange is performed in the first tank, the chemical used in the liquid processing chamber 400 is fully drained.

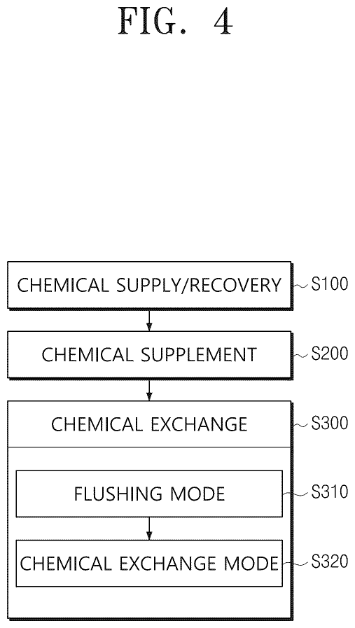

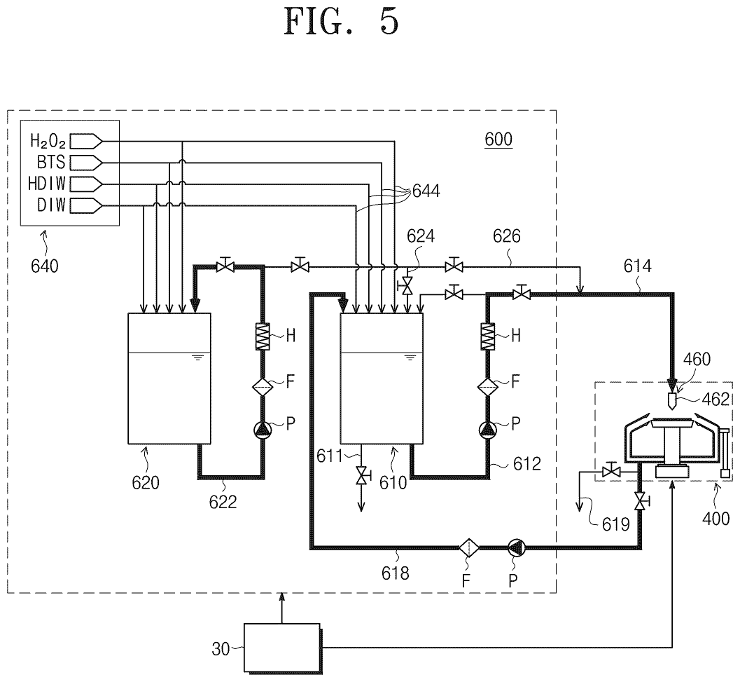

FIG. 4 is a flowchart illustrating a chemical supply method in the liquid supply apparatus and FIG. 5 to FIG. 7 are views sequentially showing the chemical supply method.

Referring to FIG. 4 to FIG. 11, the chemical supply method may include a chemical supply/recovery step S100, a chemical supplement step S200, and a liquid exchange step S300.

As shown in FIG. 5, in the chemical supply/recovery step, the chemical stored in the first tank 610 is supplied to the liquid processing chamber 400 and the chemical used in the liquid processing chamber 400 is recovered to the first tank 610. For the chemical that is recovered to the first tank 610, it is preferable to discard the chemical used in the early stage of the chemical used in the liquid processing chamber 400 and recover only the chemical used thereafter.

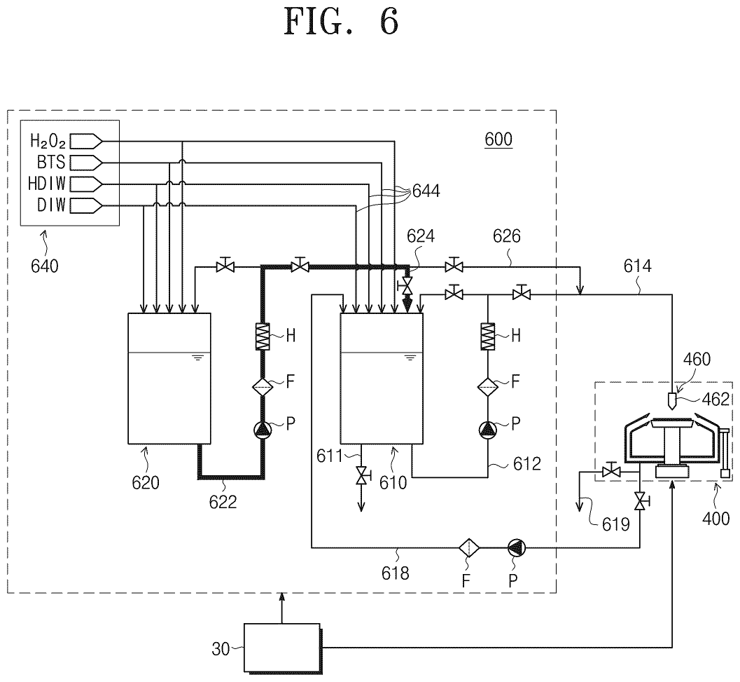

As shown in FIG. 6, in the chemical supplement step S200, the first tank 610 is supplemented with the chemical in the second tank 620. The chemical supplement step S200 supplements the first tank 610 with a chemical, as needed, from the second tank 620 so that a specific component of the chemical stored in the first tank 610 is maintained below a predetermined concentration. In this case, the amount of the chemical that is added may be the difference (amount of loss) between the supply amount that is supplied to the liquid processing chamber 400 and the recovery amount that is recovered to the first tank 610 from the liquid processing chamber 400.

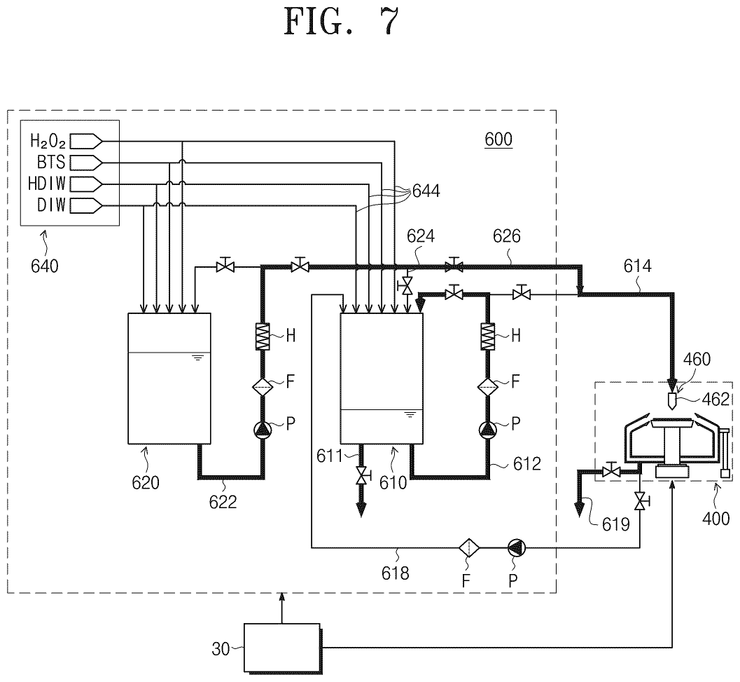

As shown in FIG. 7, the liquid exchange step S300 replaces the chemical in the first tank 610 when the chemical stored in the first tank 610 reaches a lifetime. The liquid exchange step S300 may be performed before the chemical lifetime of the chemical supply apparatus is reached. For example, when the chemical lifetime is 24 hours, chemical exchange may be performed when there is 1 hour remaining in the chemical lifetime. In a flushing mode S310, a chemical that is the same as the chemical that is used in processes is used as the flushing chemical that is supplied to the first tank 610. Accordingly, after flushing, it is possible to prevent deviation of the chemical concentration when a new chemical is supplied to the first tank 610.

In the liquid exchange step S300, a chemical is supplied to the liquid processing chamber 400 from the second tank 620. That is, in the liquid exchange step S300, the chemical in the second tank 620 is supplied to the liquid processing chamber 400 and the chemical used in the liquid processing chamber 400 is fully drained through the drain line 619. The liquid exchange step S300 drains the chemical accommodated in the first tank 610, feeds a flushing liquid into the first tank 610 and then circulates and drains the flushing chemical, and supplies a new chemical to the first tank 610, thereby achieving liquid exchange.

The flushing mode S310 is a process of draining the chemical accommodated in the first tank 610 and feeding a flushing liquid into the first tank and then circulating and draining the flushing chemical. The flushing chemical is supplied only in the amount necessary to flush the first tank 610 and the first circulation line 612. For example, assuming the storage capacity of the first tank 610 is 70 L, the flushing chemical that is fed into the first tank 610 may be 10 L. The flushing mode S310 may be performed repeatedly two time to five times to maximally remove the chemical remaining in the first circulation line 612. As described above, it is possible to secure a process margin by removing the chemical remaining in the first circulation line of the first tank 610 and it is possible to prepare a fresh chemical through dilution and discharge of Ti from the first circulation line 612. The heater installed in the first circulation line 612 is not operated in the flushing mode. A liquid exchange mode S320 supplies a new chemical to the first tank 610 after the flushing mode is finished. The new chemical is supplied from the chemical supplier 640. When a new chemical is supplied to the first tank 610, internal circulation is performed through the first circulation line 612 (heater is started).

The specification provides examples of the present invention. Further, the description provides an embodiment of the present invention and the present invention may be used in other various combination, changes, and environments. That is, the present invention may be changed or modified within the scope of the present invention described herein, a range equivalent to the description, and/or within the knowledge or technology in the related art. The embodiment shows an optimum state for achieving the spirit of the present invention and may be changed in various ways for the detailed application fields and use of the present invention. Therefore, the detailed description of the present invention is not intended to limit the present invention in the embodiment. Further, the claims should be construed as including other embodiments.

1-9. (canceled)

10. A chemical supply method that supplies a chemical to a substrate processing apparatus from a chemical processing apparatus having a first tank and a second tank, the chemical supply method comprising:
supplying a chemical stored in the first tank to the substrate processing apparatus and recovering a chemical used in the substrate processing apparatus to the first tank;
supplementing the first tank with a chemical in the second tank, as needed; and
a chemical exchange step of supplying a new chemical to the first tank when the chemical stored in the first tank reaches its lifetime,
wherein the chemical in the second tank is supplied to the substrate processing apparatus in the chemical exchange step.

11. The chemical supply method of claim 10, wherein the chemical used in the substrate processing apparatus is not recovered but is drained in the chemical exchange step.

12. The chemical supply method of claim 10, wherein a chemical used in an early stage of processing one sheet of substrate in the substrate processing apparatus is discarded and only the chemical used thereafter is recovered to the first tank.

13. The chemical supply method of claim 12, wherein the supplementing of the first tank with the chemical in the second tank as needed, supplements the first tank with the chemical from the second tank as needed, such that a specific component in the chemical stored in the first tank is maintained below a specific concentration.

14. The chemical supply method of claim 13, wherein the amount of the supplemented chemical corresponds a difference between a supply amount supplied to the substrate processing apparatus from the first tank and a recovery amount recovered to the first tank from the substrate processing apparatus.

15. The chemical supply method of claim 10, wherein the chemical exchange step drains the chemical accommodated in the first tank, feeds a flushing liquid into the first tank, circulates and then drains the flushing liquid, and supplies the new chemical to the first tank, thereby achieving liquid exchange.

16. The chemical supply method of claim 15, wherein the chemical exchange step performs a flushing process using the flushing liquid at least twice.

17. The chemical supply method of claim 15, wherein the flushing liquid is the same as the new chemical.

18. A chemical supply method that supplies a chemical to a substrate processing apparatus from a chemical processing apparatus having a first tank and a second tank, the chemical supply method comprising:
supplying a chemical stored in the first tank to the substrate processing apparatus, discarding a chemical used in an early stage of the substrate processing apparatus, and recovering only the chemical used thereafter to the first tank;
supplementing the first tank with a chemical from the second tank as needed, such that a specific component of the chemical stored in the first tank is maintained below a predetermined concentration; and
a chemical exchange step of supplying a new chemical to the first tank when the chemical stored in the first tank reaches its lifetime,
wherein, in the chemical exchange step, the chemical in the second tank is supplied to the substrate processing apparatus and the chemical used in the substrate processing apparatus is not recovered but is drained.

19. The chemical supply method of claim 18, wherein the amount of the supplemented chemical corresponds a difference between a supply amount supplied to the substrate processing apparatus from the first tank and a recovery amount recovered to the first tank from the substrate processing apparatus, and
the chemical exchange step drains the chemical accommodated in the first tank, feeds a flushing liquid into the first tank, circulates and then drains the flushing liquid, and supplies the new chemical to the first tank, thereby achieving chemical exchange.

20. The chemical supply method of claim 19, wherein the chemical exchange step performs a flushing process using the flushing liquid at least twice, and
the flushing liquid is the same as the new chemical.
